(19) United States
(12) Patent Application Publication
(10) Pub. No.: US 2025/0071905 A1
(43) Pub. Date: Feb. 27, 2025

(54) CONTROL BOARD AND METHOD FOR MANUFACTURING SAME

(71) Applicant: Hitachi, Ltd., Tokyo (JP)

(72) Inventors: Masako KATO, Tokyo (JP); Nobuhiro KUSUNO, Tokyo (JP)

(21) Appl. No.: 18/633,698

(22) Filed: Apr. 12, 2024

(30) Foreign Application Priority Data
Aug. 25, 2023 (JP) 2023-137346

(51) Int. Cl. H05K 1/18; H05K 3/34

(52) U.S. Cl. CPC H05K 1/181; H05K 3/3442; H05K 2201/10015; H05K 2201/10022; H05K 2201/10636; H05K 2201/10734

(57) ABSTRACT

A fracture due to crack growth occurring in a solder bonding portion of a wiring board of a control board in a quantum computer operating in a low-temperature environment can be prevented. There is provided a control board in which a chip electronic component having a plurality of electrodes formed thereon is connected to, by solder bonding portions, a wiring board having a wiring pattern and soldering pads formed on a front surface thereof. On the electrodes, after soldering, corner portions of the electrodes on the wiring board and entire lower surfaces thereof are covered with solder bonding portions, and corner portions of the pads on a side close to the electronic component and entire upper surfaces thereof are covered with the solder bonding portions.

### CROSS-REFERENCE TO RELATED APPLICATION

The present application claims priority from Japanese application JP2023-137346, filed on Aug. 25, 2023, the content of which is hereby incorporated by reference into this application.

### BACKGROUND OF THE INVENTION

### 1. Field of the Invention

The present invention relates to a control board suitable for use in a quantum computer implemented using a dilution refrigerator or the like, and relates to a structure of an electrode portion for bonding a quantum chip and a quantum control chip to a wiring board, the quantum chip and the quantum control chip operating at extremely low temperatures near absolute zero degree, and a method for manufacturing the structure by soldering.

### 2. Description of Related Art

Quantum computer technologies have made remarkable progress in recent years, and expectations for achieving of practical quantum computers are also increasing. Quantum computers use superconducting logic-based devices, and typically operate in a state of being cooled to an extremely low temperature in order to function in a superconducting state. PTL 1 discloses a quantum computing device in which a quantum device die and a control circuit die for controlling an operation of the quantum device die are disposed on a board. The quantum device and the board are connected by solder bumps or the like. In PTL 2, an electronic component is provided with an end surface electrode having a height equal to or less than two-thirds of an end surface height on an end surface of a substantially rectangular main body 1, and a pad portion of a printed board is formed to have a height equal to or less than twice the end surface height h from a position of the end surface electrode, thereby appropriately controlling solder wetting and wall thickness and forming a solder fillet into an ideal shape. However, in PTL 2, an operation under room temperature is assumed, and use under an extremely low-temperature environment is not assumed.

### CITATION LIST

### Patent Literature

PTL 1: JP2019-537239A
PTL 2: JP2009-4490A

### SUMMARY OF THE INVENTION

The quantum computer operates at extremely low temperatures near absolute zero degree. In a wiring board on which a quantum chip, a quantum control chip, and various electronic components are mounted, LSIs and various electronic components are mounted on the wiring board with a bonding material. The components may cause brittle fracture at extremely low temperatures, and it is important to improve the brittle fracture. In the quantum computer, solder is often used for bonding an electrode on a wiring board and an electronic component. In the case of using solder, members to be bonded and the solder may each shrink at extremely low temperatures, and cracking may occur between the members due to a difference in linear expansion coefficient of each components, resulting in a failure. In the case where the electronic component and the wiring board are bonded to each other with solder containing tin (Sn) as a main component, allotropic transformation occurs when left at low temperatures, which may impair bonding reliability. In PTL 1, reliability of a bonding portion of the electronic component at extremely low temperatures is mentioned, but a bonding structure between the electrode and the solder material is not mentioned.

The invention has been made in view of the above problems, and an object of the invention is to prevent a low-temperature brittle fracture of a component and interfacial cracking of a solder bonding portion and improve bonding reliability of a surface-mounted electronic component in a control board on which a quantum chip, a quantum control chip, and other electronic components are mounted, the quantum chip and the quantum control chip operating at extremely low temperatures.

Another object of the invention is to implement an improved manufacturing method using soldering for improving a solder bonding state of a surface-mounted electronic component connected to a circuit board by soldering at extremely low temperatures.

Typical features of the invention disclosed in the present application will be described below.

According to one feature of the invention, a control board that operates in a low-temperature environment having an absolute temperature of 77K or lower is provided. The control board includes: a surface-mounted electronic component having an electrode formed on a bottom surface thereof; a wiring board having a wiring pattern and a pad formed on a front surface thereof, the pad connecting the electrode of the electronic component; and a solder bonding portion disposed on the pad, the solder bonding portion containing tin (chemical symbol Sn) as a main component and soldering the pad and the electrode. The solder bonding portion is formed to cover an outer corner portion of the electrode on a side close to the wiring board and an entire surface adjacent to the outer corner portion, and to cover a corner portion of the pad on a side close to the electronic component and an entire surface adjacent to the corner portion. The electronic component is, for example, a chip resistor or a chip capacitor. After soldering, solder is covered up to an upper outer corner portion of the electrode which is far from the wiring board.

According to another feature of the invention, when installing a chip resistor and a chip capacitor, the wiring board is manufactured such that an inner corner portion of the pad on the wiring board is shifted to be located outside a lower inner corner portion of the corresponding electrode on the electronic component when viewed from a center of the electronic component, and an outer corner portion of the pad on the wiring board is shifted to be located outside a lower outer corner portion of the corresponding electrode on the electronic component when viewed from the center of the electronic component. A first shift amount to outside of the inner corner portion of the pad is less than a second shift amount to outside of the outer corner portion of the pad.

According to still another feature of the invention, the electronic component is a surface-mounted component having a plurality of flat plate-shaped electrodes formed on a bottom surface thereof, a plurality of flat plate-shaped pads corresponding to the electrodes are formed on the wiring board, an entire configuration is heated and melted in a state in which a solder material is sandwiched between the electrodes and the pads, soldering is performed such that lower corner portions of the electrodes on all the electronic components and entire surfaces adjacent to the lower corner portions, and upper corner portions of all the pads and entire surfaces adjacent to the upper corner portions are covered with solder, and the soldering can be operated in a low-temperature environment having an absolute temperature of 77K or lower. The soldering is performed by, for example, BGA bonding or QFN bonding.

According to the invention, in the control board for a quantum computer having an electrode structure covered with solder, the soldering is performed such that the lower corner portions of the electrodes on all the electronic components and the entire surfaces adjacent to the lower corner portions, and the upper corner portions of all the pads and the entire surfaces adjacent to the upper corner portions are covered with the solder, so that interfacial cracking around the solder bonding portion that is caused by low temperature can be effectively prevented. Configurations and effects of the invention will become apparent in the entire description.

### BRIEF DESCRIPTION OF THE DRAWINGS

FIG. 1 is a top view of a control board according to an embodiment of the invention;

FIG. 2 is a cross-sectional view taken along a line A-A in FIG. 1;

FIG. 3 is a cross-sectional view showing a state immediately before an electronic component in FIG. 2 is installed to the control board;

FIG. 4 is a partial cross-sectional view showing a bonding state of a solder bonding portion according to a modification of the present embodiment;

FIG. 5 is a partial longitudinal cross-sectional view 4 wiring board showing a second embodiment of the invention (corresponding to a B-B portion in FIG. 1);

FIGS. 6A and 6B are diagrams showing a state after the soldered wiring board is left in an extremely low-temperature environment, in which FIG. 6A shows a soldering method in the related art, and FIG. 6B shows a soldering method according to the second embodiment; and

FIGS. 7A and 7B are cross-sectional photographs of portions shown in FIGS. 6A and 6B.

### DESCRIPTION OF EMBODIMENTS

### Embodiment 1

Hereinafter, embodiments of the invention will be described with reference to the drawings. In the following drawings, the same parts are denoted by the same reference numerals, and repeated description thereof is omitted. In the present description, inside and outside directions, and up and down directions are described as directions shown in the drawings.

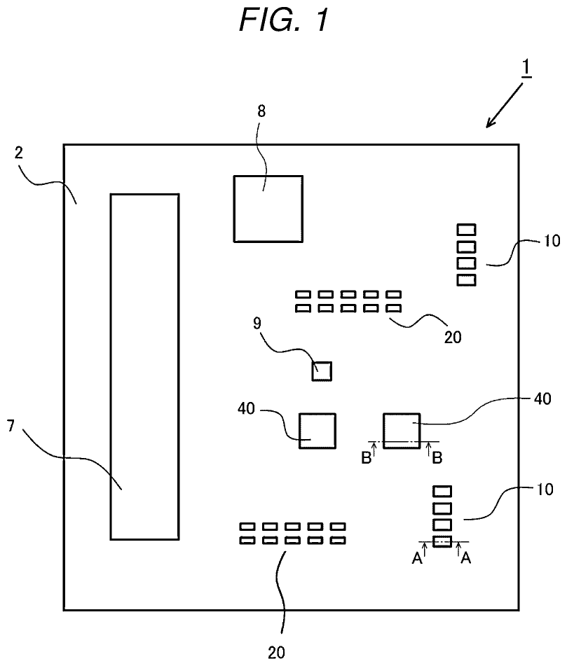

FIG. 1 is a top view of a control board 1 according to an embodiment of the invention. The control board 1 is mounted on a plate in a dilution refrigerator, which is one of components in a quantum computer, and mainly operates at an extremely low temperature having, for example, an absolute temperature of about 4K to 77K. When using a dilution refrigerator, a temperature of a cooling stage is often divided into 50 K and 4K. In a cooling method using liquid nitrogen, since a boiling point of the liquid nitrogen is 78 K, a main operating range of the control board of the invention is a temperature range of 77K or lower. The temperature range of 77K or lower is merely an example, and the invention is not excluded from being implemented in a temperature range higher than the range.

The control board 1 has a quantum bit control circuit (RFGEN BVG) or the like mounted on a wiring board 2, and is mounted on, for example, a 4K plate of a dilution refrigerator (not shown). Therefore, an environment in which the control board 1 operates is an extremely low temperature of about 4K to more than 10K. The control board 1 is implemented by mounting a control LSI 9 using a silicon chip, electronic components 20 such as a chip resistor or electronic components 10 such as a chip capacitor, a connector component 7, a package component 8, and the like on the wiring board 2. The control board 1 shown in FIG. 1 is, for example, a small daughter board of about 5 cm×6 cm, and a quantum chip bonded using silver paste or the like, a quantum bit control circuit, and the like are mounted on a motherboard (not shown). The control board 1 of the invention is applicable regardless of size.

In a structure in which an electronic component is bonded to the wiring board 2, a surface-mounted component is fixed by being bonded to a pad serving as a connection portion of the wiring board 2 by printing solder paste on the wiring board 2 and heating and melting the solder paste. For the connector component 7, which is mounted by inserting a connector terminal into a through hole (not visible in the drawing), the solder paste is printed on the through hole of the wiring board 2, and then the terminal is inserted and bonded by heating and melting. After a plurality of terminals of the connector component 9 are inserted into a plurality of through holes of the wiring board 2, the terminals can be bonded to a board electrode by flow solder, spot solder, or the like. A composition of the solder material is generally Sn-3.0Ag-0.5Cu, and Bi, Sb, Ni, or the like may be contained in order to improve reliability. In the present description, solder before being heated and melted is simply referred to as a “solder material”, and solder after being cooled with a defined shape is simply referred to as “solder” or a “solder bonding portion”. Since the solder before being heated and the solder after being heated are the same material, they are simply referred to as “solder” regardless of before and after heating.

In many electronic components, a surface-mounted component or an insertion component is connected to the wiring board 2 via solder, and an intermetallic compound is formed at an interface between the pad and the solder and between the electrode and the solder on the control board 1 after soldering. At extremely low temperatures, due to a difference in linear expansion coefficient of each element such as solder or an electrode, deformation occurs under a temperature load, and cracks grow at an interface between the intermetallic compound and the electrode, which may cause a decrease in lifespan of the control board 1. At extremely low temperatures, which are different from room temperature, there is a high possibility that cracks grow in the solder and fractures occur due to cleavage, thereby impairing the reliability of the control board 1.

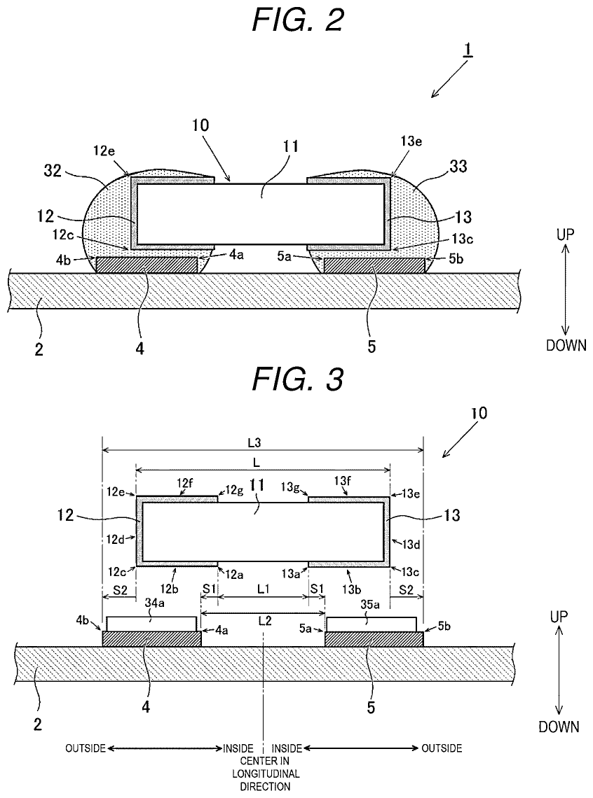

FIG. 2 is a partial cross-sectional view of the control board 1, that is, a cross-sectional view taken along a line A-A in FIG. 1, and shows a cross section after the electronic component 10 is soldered to the wiring board 2. The electronic component 10 is a capacitor housed in a main body portion 11 made of ceramic or the like, and is commercially available as a chip-side capacitor. The electronic component 10 is a rectangular parallelepiped body in a top view as shown in FIG. 1, the main body portion 11 accommodates an electronic element (not shown) inside an exterior, a cover, a package, or the like made of a member through which electricity does not pass, and a longitudinal cross-sectional shape thereof is, for example, a rectangle. Two electrodes 12 and 13 for wiring are provided on a short-side portion of the main body portion 11 in a longitudinal sectional view. The electrode 12 is made of metal and formed to extend over a part of a front surface (upper surface), a short-side side surface, and a part of a bottom surface (lower surface) of the rectangular parallelepiped main body portion 11. The electrode 13 is made of metal, has a symmetrical shape with the electrode 12, and is formed extend over a part of the front surface, a short-side side surface, and a part of the bottom surface of the rectangular parallelepiped main body portion 11.

The electronic component 20 including a chip resistor is similar in shape to the electronic component 10, and a soldering method of the present embodiment and a pattern arrangement of a control board for soldering are not affected by what kind of electronic component is housed in the main body portion 11, and thus the soldering method in FIGS. 2 to 4 can be similarly applied to the electronic component 20.

The wiring board 2 is, for example, a printed board, which can be used particularly in an extremely low-temperature environment. A plurality of wiring patterns are printed on at least the front surface of the wiring board 2, and a plurality of pads 4 and 5 are formed with parts of the wiring patterns exposed. The plurality of pads 4 and 5 are provided to correspond to the number of the electrodes 12 and 13 of the electronic component 10, and are portions to which the solder material adheres after melting. The electronic component 10 is fixed to the pads 4 and 5 by soldering, and an electrical conduction state between the electrodes 12 and 13 and the pads 4 and 5 is established.

Solder bonding portions 32 and 33 shown in FIG. 2 are in a state after the solder material is heated and melted and then cooled and solidified. The solder bonding portion 32 is formed by cooling a solder material before being heated and melted, has a substantially ball-shaped shape as a whole, and is formed such that substantially the entire electrode 12 and substantially the entire metal pad 4 are provided inside the ball-shaped outer surface formed by solder. In the solder bonding portion 33, substantially the entire electrode 13 and substantially the entire metal pad 5 are covered with solder. As described above, the solder bonding portions 32 and 33 have a shape that is convex downward from the bottom surfaces of the electrodes 12 and 13 of the electronic component 10, convex laterally from the side surfaces, and convex upward from the upper surfaces. The solder bonding portion 33 is formed symmetrically with the solder bonding portion 32. In order to form such solder bonding portions 32 and 33, it is important to adjust an amount of the solder material before performing reflow soldering, define respective size and relative position relationships between the electrode 12 and the pad 4, and define respective size and relative position relationships between the electrode 13 and the pad 5.

FIG. 3 is a cross-sectional view showing a state immediately before the electronic component 10 in FIG. 2 is installed to the control board 1. A size of the electronic component 10 in a longitudinal direction is L, and the front surface and the bottom surface of the main body portion 11 of the electronic component are covered with the metal electrodes 12 and 13 except for a portion having a length L1 at a center in the longitudinal direction. The shape is widely adopted in commercially available chip resistors and chip capacitors. In the present embodiment, in order to enable the soldering method according to the invention, the arrangement and size of the pads 4 and 5 are devised. When viewed from an electrode 12 side, a position of a corner portion 4b of the pad 4 is set to be shifted to outside from an outer end portion of the pad 4 by a distance S2 in the longitudinal direction, and a position of a corner portion 4a of the pad 4 is set to be shifted to outside from a corner portion 12a of the electrode 12 by a distance S1 in the longitudinal direction. As for definitions of the outside and inside, a side closer to a center position of the rectangular parallelepiped electronic component 10 in the longitudinal direction is referred to as the inside, and a side farther from the center position is referred to as the outside, as indicated by arrows in FIG. 3.

On an electrode 13 side, a position of a corner portion 5b of the pad 5 is set to be shifted to outside from an end portion 13c of the electrode 13 by the distance S2 in the longitudinal direction, and a position of a corner portion 5a of the pad 5 is set to be shifted to outside from a corner portion 13a of the electrode 13 by the distance S1 in the longitudinal direction. Here, there is a relationship of S2>S1. As described above, the wiring pattern is formed such that a distance between the pads 4 and 5 is L2, which is wider than the distance L1 between the electrodes 12 and 13, and thus the inner end portions 12a, 13a of the electrodes 12, 13 are shifted closer to the center than the inner end portions 4a, 5a of the pads 4, 5 in the longitudinal direction.

Solder materials 34 and 35 are formed on the pads 4 and 5 in advance by printing or coating. Before performing soldering, solder balls (not shown) may be added to the solder materials 34 and 35 to adjust the amount of the solder material. Thereafter, by heating the wiring board 2 and an entire mounted object, the solder materials 34 and 35 and the solder balls (not shown) are heated and melted, and then cooled and solidified to form the solder bonding portions 32 and 33. The solder bonding portions 32 and 33 are formed in a substantially spherical shape that is convex outward due to the surface tension. In this way, a soldering state shown in FIG. 2 is obtained. In the soldering state in FIG. 2, the upper side and inner corner portion 4a of the pad 4 and the upper side and inner portion 5a of the pad 5 are completely embedded in the solder bonding portions 32 and 33. Since an outer end portion 12c of the electrode 12 facing the pad 4 is shifted to inside (a center side of the main body portion 11) from an end portion of the corner portion 4b of the facing pad 4, the facing outer side surface 4b of the pad 4 is also covered with the solder bonding portion 32. Similarly, the upper side and inner corner portion 5a of the pad 5 and the upper side and outer corner portion 5b of the pad 5 are completely embedded in the solder bonding portion 33. Since the outer end portion 13c of the electrode 13 facing the pad 5 is shifted to inside (the center side of the main body portion 11) from an end portion of the facing corner portion 5b, the facing outer side surface 5b of the pad 5 is also covered with the solder bonding portion 33. As a result, both of the outer corner portions 12c and 13c of the electrodes 12 and 13 are embedded in the solder bonding portions 32 and 33.

Further, by adjusting the amount of solder to be melted, outer corner portions 12e and 13e on the upper surfaces of the electrodes 12 and 13 can also be completely covered with the solder bonding portions 32 and 33. The corner portions 12a, 12g, 13a, and 13g shown in FIG. 3 may not be covered with the solder bonding portions 32 and 33.

As described above, in the present embodiment, the corner portions 12c and 13c and the corner portions 4a, 4b, 5a, and 5b, which are likely to be starting points of the interfacial cracking caused by low temperature, are completely embedded in the solder bonding portions 32 and 33, and thus the occurrence of the interface cracking can be effectively prevented. Although only one of the electronic components 10 shown in FIG. 1 has been described in the examples of FIGS. 2 and 3, a large number of electronic components 10 mounted on the control board 1, the chip capacitor 20, and other electronic components (not shown) having the same terminal structure are soldered by the same method. For example, a chip resistor and a chip capacitor each include two electrodes on the main body portion 11, and the present embodiment can be similarly applied to a case in which one or a plurality of electrodes are provided on opposite short sides or long sides of the same length of the rectangular parallelepiped main body portion 11, a case in which an electrode is provided only on a short side or long side of a component, and a case in which one or a plurality of electrodes are provided on any or all of sides, respectively.

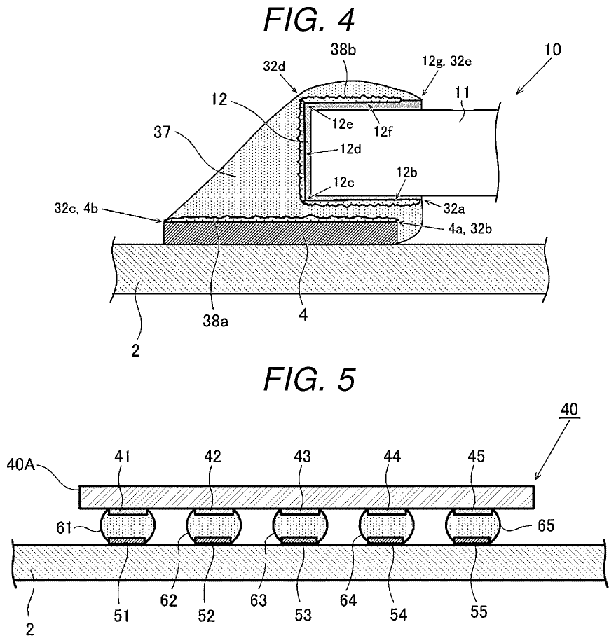

A bonding state of a solder bonding portion 37 according to a modification of the present embodiment will be described with reference to FIG. 4. When a solder material is heated and melted to form the solder bonding portion 32, an intermetallic compound 38a is formed at an interface between the pad 4 and the solder bonding portion 32. Similarly, an intermetallic compound 38b is also formed at an interface between the electrode 12 side and the solder bonding portion 33 shown in FIG. 2. The intermetallic compound may grow due to heating and melting during manufacturing. The solder bonding portion 37 formed from the side surface of the electronic component 10 to an outer peripheral portion of the pad 4 in FIG. 4 has a gentle shape rather than a convex shape protruding to outside of the solder bonding portion 32 shown in FIG. 2. It is considered that even in this case, since a stress applied to the solder bonding portion on the outside of the component is smaller than that applied to the solder bonding portion on the lower electrode of the component, cracks starting from this side are less likely to occur.

### Embodiment 2

Next, a second embodiment of the invention will be described with reference to FIGS. 5 to 7. FIG. 5 is a partial longitudinal cross-sectional view of the wiring board 2 showing the second embodiment of the invention, which corresponds to, for example, a B-B portion in FIG. 1. As shown in FIG. 5, an electronic component 40 is an area-array electronic component, and includes a main body portion 40A and electrodes 41 to 45. Solder balls are formed on the electrodes 41 to 45 and the like. A plurality of pads 51 to 55 are disposed at positions facing the plurality of electrodes 41 to 45 formed on a bottom surface of the main body portion 40A of the electronic component 40. The electrodes 41 to 45 are connected to the plurality of pads 51 to 55 by substantially spherical solder bonding portions 61 to 65. In the solder bonding portions 61 to 65, the solder balls are disposed between the electronic component 40 and the wiring board 2, and then an entire configuration (the wiring board 2, the solder balls, the electronic component 40, and the like) is heated to heat and melt the solder bonding portions 61 to 65. Cooled solder balls 66 to 68 and the like are the solder bonding portions 61 to 65 and are made of the same material. As can be seen from FIG. 5, the solder bonding portions 61 to 65 each have a barrel shape that convexly bulges to outside in a longitudinal cross-sectional view.

As described above, in the second embodiment, shapes of the solder bonding portions 61 to 65 after soldering are controlled to have desired shapes with respect to the electrodes of the electronic component 40 to be surface-mounted. By heating and melting an entire configuration in a state in which the solder bonding portions 61 to 63 and the like are sandwiched between the electrodes 41 to 45 and the like and the pads 51 to 53 and the like on the electronic component 40 side, lower corner portions of all the electrodes of the electronic component 40 and entire side surfaces (surfaces adjacent to the lower corner portions) are located inside the solder bonding portions 61 to 65 after melting and are covered with solder. According to the second embodiment, upper corner portions and entire side surfaces (surfaces adjacent to the upper corner portions) of the pads 51 to 58 and the like for installing the electronic components mounted on the wiring board 2 can be covered with the solder bonding portions 61 to 65 and the like after cooling. The solder material prepared on the upper surfaces of the pads 51 to 55 before heating may be a solder material for forming a solder layer on the pads 51 to 55 by printing or coating, and a method of preparing the solder material is freely determined.

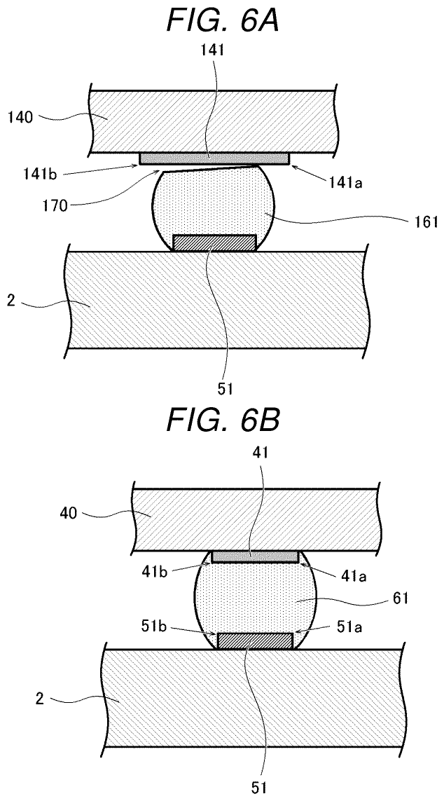

FIGS. 6A and 6B are diagrams showing a soldering state of the wiring board, and in FIG. 6A, a pad 51 on the wiring board 2 side is formed to be relatively smaller than an electrode 141 of an electronic component 140. A solder bonding portion 161 is bonded to a lower surface of the electrode 141, and lower corner portions 141a and 141b of the electrode 141 and side surfaces extending upward from the lower corner portions 141a and 141b are exposed without being covered with the solder bonding portion 161. On the pad 51 side, not only the upper surface but also the side surface is covered with the solder bonding portion 161, and corner portions 51a and 51b on an upper surface of the pad 51 are located inside the solder bonding portion 161. On the other hand, FIG. 6(B) is a bonding method shown in the second embodiment, in which an entire lower surface and a side surface of the electrode 41 provided in the electronic component 40 and an entire upper surface and a side surface of the pad 51 are exposed before soldering, and the solder material melts during heating, spreads to cover side surfaces of the electrode 41 and the pad 51, and then is solidified, and thus the electrode 41 and the pad 51 are covered with the solder material. As a result, corner portions 41a and 41b of the electrode 41 and corner portions (four corner portions are present on a lower surface) of portions that are not shown in the drawing are also covered with the solder bonding portion 61.

In the case where the control boards shown in FIGS. 6A and 6B are left in a low-temperature environment of 77K for 300 hours, it is found that since the control board in FIG. 6A does not have the solder bonding portion 161 formed on the side surface of the electrode 141, and is bonded in one plane, on the electrode 141 side, a fracture due to crack growth occurs from a bonded portion near the corner portion 141b in an inside direction, as shown by an arrow 170. On the other hand, there was no cracks in the control board according to the second embodiment, and the bonding state between the electrode 14 and the solder bonding portion 61 was good.

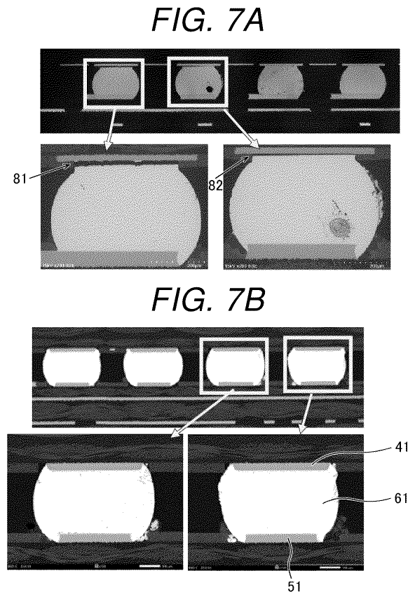

FIGS. 7A and 7B are photographs when states shown in FIGS. 6A and 6B are confirmed through an experiment. FIG. 7A shows a configuration shown in FIG. 6A, in which the electrode 141 and the solder bonding portion 161 are in surface contact with each other only on one surface. When the control board was left at an extremely low temperature, each component was contracted, and cracking occurred at an interface between components as indicated by arrows 81 and 82 due to a difference in linear expansion coefficient. On the other hand, in the bonding method according to the second embodiment shown in FIG. 7B, a bonded structure is adopted in which the side surface of the electrode 41 is covered with the solder bonding portion 61, and the solder bonding portion 61 is also bonded to the lower surface of the electrode 41 and the side surface adjacent to the lower surface. Therefore, it is confirmed that even when each component contracts, cracks do not grow at the interface to cause peeling, and bonding reliability in a low-temperature environment can be improved.

As described above, according to the invention, when a bonded structure in which a side surface and a corner portion of an electrode are covered with solder and the electrode is not exposed in a bonding portion between the electrode on a board and the solder or a bonding portion between the electrode of an electronic component and the solder is adopted for a structure in which a general surface-mounted component is bonded with solder, a starting point of the interfacial cracking caused by low temperature can be protected, a lifespan of the bonding portion between the solder and the electrode can be extended. Since it is not necessary to change the material and composition of the solder from the related art, a commercially available product containing general copper and silver can be used. The invention is particularly suitable for use in outer space and for a control circuit used in a quantum computer that operates in an extremely low-temperature environment of 77K or lower using helium gas, and an electronic device that operates in an extremely low-temperature environment.

Although the invention has been described based on the two embodiments in the present description, the invention is not limited to the above-described embodiments, and various modifications can be made without departing from the gist of the invention. For example, in the above-described control board, a structure is adopted in which in the solder bonding portion for bonding the wiring board and the electronic component, the solder bonding portion contains Sn as a main component, soldering surfaces of the pad of the wiring board and the electrode of the electronic component, the corner portions thereof, and the side surface in contact with the corner portions are covered with the melted and cooled solder, and the electrode is not exposed. With such a structure, the respective dimensions, ratios, shapes, and the like are not limited to those described in the embodiments. Further, the type, shape, and size of the electronic component to be used, and the configuration as to whether the wiring board or the like is made into a single layer or a multilayer may be freely determined.

What is claimed is:

1. A control board that operates in a low-temperature environment having an absolute temperature of 77 K or lower, the control board comprising:
a surface-mounted electronic component having an electrode formed on a bottom surface thereof;
a wiring board having a wiring pattern and a pad formed on a front surface thereof, the pad connecting the electrode of the electronic component; and
a solder bonding portion disposed on the pad, the solder bonding portion containing Sn as a main component and soldering the pad and the electrode, wherein
the solder bonding portion covers an outer corner portion of the electrode on a side close to the wiring board and an entire surface adjacent to the outer corner portion, and covers a corner portion of the pad on a side close to the electronic component and an entire surface adjacent to the corner portion.

2. The control board according to claim 1, wherein
after the pad is soldered, the electronic component is covered with solder up to an upper outer corner portion of the electrode which is far from the wiring board.

3. The control board according to claim 2, wherein
the electronic component is a chip resistor or a chip capacitor including two of the electrodes.

4. The control board according to claim 2, wherein
an inner corner portion of the pad on the wiring board is shifted to be located outside a lower inner corner portion of the corresponding electrode on the electronic component when viewed from a center of the electronic component, and
an outer corner portion of the pad on the wiring board is shifted to be located outside a lower outer corner portion of the corresponding electrode on the electronic component when viewed from the center of the electronic component.

5. The control board according to claim 4, wherein
a first shift amount to outside of the inner corner portion of the pad is less than a second shift amount to outside of the outer corner portion of the pad.

6. The control board according to claim 1, wherein
a plurality of the electronic components are mounted on the wiring board,
a plurality of the flat plate-shaped electrodes are formed on bottom surfaces of the electronic components,
a plurality of flat plate-shaped pads corresponding to the electrodes are formed on the wiring board,
an entire configuration is heated and melted in a state in which a solder material is sandwiched between the electrodes and the pads, and
soldering is performed such that lower corner portions of the electrodes on all the electronic components and entire surfaces adjacent to the lower corner portions, and upper corner portions of all the pads and entire surfaces adjacent to the upper corner portions are covered with solder.

7. The control board according to claim 1, wherein
the soldering is performed by BGA bonding or QFN bonding, and
the outer corner portion of the electrode on the electronic component to be mounted on the side close to the wiring board and the entire surface adjacent to the outer corner portion are covered with solder, and the corner portion of the pad on the side close to the electronic component and the entire surface adjacent to the corner portion are covered with solder.

8. A control board that operates in a low-temperature environment having an absolute temperature of 77 K or lower, wherein
a plurality of surface-mounted electronic components having a plurality of electrodes formed on bottom surfaces thereof are connected to, by a solder material, a wiring board having a wiring pattern and pads formed on a front surface thereof, the pads connecting the electrodes of the electronic components,
the plurality of electrodes are disposed in inner portions of the bottom surfaces of the electronic components that are not in contact with edge portions, and
after soldering, corner portions of the electrodes on a side close to the wiring board and entire lower surfaces adjacent to the corner portions are covered with solder, and corner portions of the pads on a side close to the electronic components and entire upper surfaces adjacent to the corner portions are covered with solder.

9. The control board according to claim 8, wherein
area sizes of lower surfaces of the plurality of electrodes are larger than area sizes of upper surfaces of the pads facing the plurality of electrodes.

10. The control board according to claim 9, wherein
the electronic components are chip resistors or chip capacitors.

11. A method for manufacturing a control board in which an electronic component having a plurality of electrodes formed on a bottom corner portion thereof is connected to, by a solder material, a wiring board having a wiring pattern and pads formed on a front surface thereof, the pads connecting the electrodes of the electronic component, the method comprising:
disposing a center position of the pad on the control board to be located outside a center position of the electrode to be bonded with respect to a center position of the electronic component;
performing soldering of the electrode and the pad by disposing a solder material containing Sn as a main component on the pad, disposing the electrode of the electronic component on the solder material, and performing heating and melting; and
performing soldering by adjusting an amount of the solder material such that after the soldering, a corner portion of the electrode on a side close to the wiring board and an entire lower surface adjacent to the corner portion are covered with the solder material, and a corner portion of the pad on a side close to the electronic component and an entire upper surface adjacent to the corner portion are covered with the solder material.

12. The method for manufacturing a control board according to claim 11, wherein
the electrodes each have an entire short-side side surface of the electronic component, a lower surface extending from the short-side side surface to a part of a bottom surface, and an upper surface extending from the short-side side surface to a part of a front surface, and
during the soldering, solder is formed such that an upper corner portion of the electrode which is far from the wiring board is covered with solder.

13. The method: for manufacturing a control board according to claim 12, wherein
the electronic component is a chip resistor including two of the electrodes, and
the wiring board is manufactured such that an inner corner portion of the pad on the wiring board is shifted to be located outside a lower inner corner portion of the corresponding electrode on the electronic component when viewed from a center of the electronic component, and an outer corner portion of the pad on the wiring board is shifted to be located outside a lower outer corner portion of the corresponding electrode on the electronic component when viewed from the center of the electronic component.
